(19) United States
(12) Patent Application Publication
(10) Pub. No.: US 2015/0123692 A1
(43) Pub. Date: May 7, 2015

(54) APPARATUS AND METHOD OF TESTING AN ELECTRONIC DEVICE

(71) Applicant: Samsung Electronics Co., Ltd., Suwon-si (KR)

(72) Inventors: Ki-Ryong Woo, Gwangmyeong-si (KR); Hyuck-Soo Jeon, Cheonan-si (KR); Jae-Il Choi, Hwaseong-si (KR)

(21) Appl. No.: 14/313,022

(22) Filed: Jun. 24, 2014

(30) Foreign Application Priority Data
Nov. 6, 2013 (KR) 10-2013-0134119

(51) Int. Cl. G01R 31/26; G01R 1/04

(52) U.S. Cl. CPC G01R 31/2607; G01R 1/0416
USPC 324/756.05

(57) ABSTRACT

An apparatus for testing an electronic device may include a field programmable gate array (FPGA), a test board, a test channel and a loop channel. The electronic device may be electrically connected to the test board. The test channel may be electrically connected between the electronic device and the FPGA via the test board. The loop channel may extend from the FPGA, may be connected to the FPGA via the test board, and may be used to test the test board.

### CROSS-RELATED APPLICATION

This application claims priority under 35 USC §119 to Korean Patent Application No. 2013-134119, filed on Nov. 6, 2013 in the Korean Intellectual Property Office (KIPO), the contents of which are herein incorporated by reference in their entirety.

### BACKGROUND

1. Field

Exemplary embodiments in accordance with principles of inventive concepts relate to an apparatus and a method of testing an electronic device such as, for example, a semiconductor chip.

2. Description of the Related Art

Generally, a semiconductor chip may be tested using a built off self test (BOST), which BOST may employ a field programmable gate array (FPGA), a connector and a test board. The FPGA may include variable logic which may be suitably configured for the particular kind of semiconductor chip under test. The connector may be electrically connected between the FPGA and the test board, upon which the semiconductor chip may be mounted. The FPGA may supply a test signal to the semiconductor chip via the connector and the test board to test electrical characteristics of the semiconductor chip.

Distortions of the test signal may occur, for example, through poor connections between the test board and FPGA. Poor connections may be the result of distortions of the test board, such as a test board bent by the semiconductor chip mounted thereon, a defect in the connector, or, even, a slight wearing of the connector. Distortion of the test signal may lead to inaccurate results in the testing of the electrical characteristics of the semiconductor chip. An additional check board may be used to correct the distorted test signal, but, because the BOST must be suspended during the correction process, the time devoted to testing may be increased, with a concomitant decrease in throughput.

### SUMMARY

Exemplary embodiments of an apparatus for testing an electronic device in accordance with principles of inventive concepts include a field programmable gate array (FPGA) configured to test an electronic device; a test board electrically connected to the electronic device; a test channel electrically connected between the electronic device and the FPGA via the test board; and a loop channel extending from the FPGA to the test board, and returning to the FPGA, the loop channel configured to test the test board.

In exemplary embodiments in accordance with principles of inventive concepts a loop channel includes an input line extending from the FPGA; a loop line extending from the input line in the test board; and an output line extending from the loop line and connected to the FPGA.

In exemplary embodiments in accordance with principles of inventive concepts a loop line is configured to surround the electronic device on the test board.

In exemplary embodiments in accordance with principles of inventive concepts a loop line includes a first loop line extending on a first plane and configured to surround the electronic device on the test board; and a second loop line extending on a second plane and configured to surround the electronic device on the test board.

In exemplary embodiments in accordance with principles of inventive concepts a tester includes a connector arranged between the FPGA and the test board, the test board detachably connected to the connector.

In exemplary embodiments in accordance with principles of inventive concepts a connector includes a first connector and a second connector respectively arranged at opposite sides of the electronic device on the test board.

In exemplary embodiments in accordance with principles of inventive concepts a loop channel includes a first loop channel extending from the FPGA via the first connector in the test board on a first plane; and a second loop channel extending from the FPGA via the second connector in the test board on a second plane.

In exemplary embodiments in accordance with principles of inventive concepts the first loop channel and the second loop channel are configured to surround the electronic device on the test board.

In exemplary embodiments in accordance with principles of inventive concepts the first loop channel and the second loop channel are symmetrical with each other with respect to the electronic device on the test board.

In exemplary embodiments in accordance with principles of inventive concepts the first loop channel extends from a portion of the first connector adjacent to a first end of a diagonal line on the electronic device, and the second loop channel extends from a portion of the second connector adjacent to a second end of the diagonal line opposite to the first end.

In exemplary embodiments in accordance with principles of inventive concepts the electronic device comprises a semiconductor chip.

In exemplary embodiments in accordance with principles of inventive concepts a method of testing an electronic device includes inputting a test signal to a test board via a loop channel, the loop channel extending from a field programmable gate array (FPGA) configured to test the electronic device, and connected to the FPGA via the test board; measuring a signal outputted from the test board to the FPGA via the loop channel; checking the test board based on the measured signal to obtain a correction value for compensating for distortions related to the test board; applying the correction value to the test signal to obtain a corrected test signal; and supplying the corrected test signal to the electronic device through a test channel electrically connected between the electronic device and the FPGA via the test board.

In exemplary embodiments in accordance with principles of inventive concepts inputting the test signal to the test board includes supplying the test signal through the loop line configured to surround the electronic device on the test board.

In exemplary embodiments in accordance with principles of inventive concepts inputting the test signal to the test board includes supplying the test signal through a first loop line on a first plane; and supplying the test signal through a second loop line on a second plane.

In exemplary embodiments in accordance with principles of inventive concepts inputting the test signal to the test board comprises supplying the test signal through a connector.

In exemplary embodiments in accordance with principles of inventive concepts a method includes sending a test signal from a tester through a loop channel on a board upon which a semiconductor chip to be tested is mounted; receiving the test signal after passage through the channel; comparing the sent test signal with the received test signal to detect distortion of the test signal; developing a compensation signal; combining the compensation signal and test signal to form a compensated test signal; and testing the semiconductor chip using the compensated test signal transmitted through a test channel.

In exemplary embodiments in accordance with principles of inventive concepts the test signal and compensated test signal are generated by an FPGA.

In exemplary embodiments in accordance with principles of inventive concepts the loop channel does not surround the semiconductor chip.

In exemplary embodiments in accordance with principles of inventive concepts the loop channel surrounds the semiconductor chip and is distributed on two levels of the board.

In exemplary embodiments in accordance with principles of inventive concepts the loop channel includes two components, each receiving test signals from separate FPGAs.

### BRIEF DESCRIPTION OF THE DRAWINGS

Exemplary embodiments in accordance with principles of inventive concepts will be more clearly understood from the following detailed description taken in conjunction with the accompanying drawings. FIGS. 1 to 10 represent non-limiting, exemplary embodiments in accordance with principles of inventive concepts as described herein.

FIG. 1 is a plan view illustrating an apparatus for testing an electronic device in accordance with exemplary embodiments in accordance with principles of inventive concepts;

FIG. 2 is a flow chart illustrating a method of testing an electronic device using the apparatus in FIG. 1;

FIG. 3 is a plan view illustrating an apparatus for testing an electronic device in accordance with exemplary embodiments in accordance with principles of inventive concepts;

FIG. 4 is a cross-sectional view taken along a line IV-IV′ in FIG. 3;

FIG. 5 is a flow chart illustrating a method of testing an electronic device using the apparatus in FIG. 3;

FIG. 6 is a plan view illustrating an apparatus for testing an electronic device in accordance with exemplary embodiments in accordance with principles of inventive concepts;

FIG. 7 is a cross-sectional view taken along a line VII-VII′ in FIG. 6;

FIG. 8 is a flow chart illustrating a method of testing an electronic device using the apparatus in FIG. 6;

FIG. 9 is a plan view illustrating an apparatus for testing an electronic device in accordance with exemplary embodiments in accordance with principles of inventive concepts; and

FIG. 10 is a plan view illustrating an apparatus for testing an electronic device in accordance with exemplary embodiments in accordance with principles of inventive concepts.

### DETAILED DESCRIPTION

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

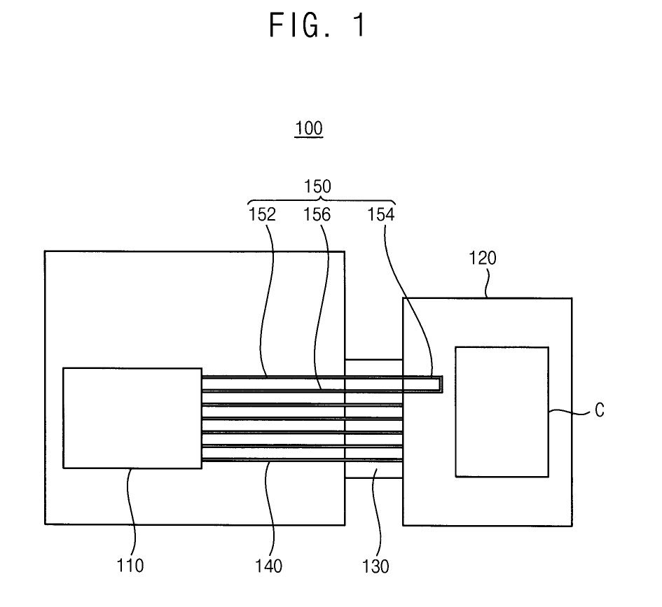

Hereinafter, exemplary embodiments in accordance with principles of inventive concepts will be explained in detail with reference to the accompanying drawings. FIG. 1 is a plan view illustrating an apparatus for testing an object, such as an electronic device, in accordance with exemplary embodiments in accordance with principles of inventive concepts. Testing apparatus 100, also referred to herein as apparatus 100 for testing an object, may include a BOST using a field programmable gate array (FPGA) 110. In exemplary embodiments in accordance with principles of inventive concepts, testing apparatus 100 may include the FPGA 110, a test board 120, a connector 130, a test channel 140 and a loop channel 150.

The FPGA 110 may include variable logic, which may be configured according to the object, such as semiconductor chip, under test, for example. In exemplary embodiments in accordance with principles of inventive concepts, the electronic device, may include a semiconductor chip C. In accordance with principles of inventive concepts, when the semiconductor chip C is changed, for example, when a different type of semiconductor chip is to be tested, test logic within FPGA 110, which may generate a test signal, may be altered to accommodate the new semiconductor chip C.

In exemplary embodiments in accordance with principles of inventive concepts, semiconductor chip C may be arranged on a central portion of an upper surface of the test board 120. The semiconductor chip C may be electrically connected to an inner circuit of the test board 120. The test board 120 could be bent, for example, due to a force generated when the semiconductor chip C is mounted on the test board 120.

The connector 130 may be arranged between the FPGA 110 and the test board 120. The test board 120 may be detachably connected to the connector 130. When the test board 120 is properly connected to the connector 130, the test signal may be supplied to the test board 120 without distortions of the test signal. However, if the test board 120 is bent, it may not be accurately connected to the connector 130. Additionally, when faults, such as an open, a short, etc., may be generated at the test board 120 due to other causes, a contact failure between the test board 120 and the connector 130 may be generated. In such cases, distortions may be generated in the test signal supplied to the test board 120.

The test channel 140 may be electrically connected between the FPGA 110 and the test board 120 via the connector 130 and may be electrically connected to the inner circuit of the test board 120. In exemplary embodiments in accordance with principles of inventive concepts, the test signal may be transmitted to the semiconductor chip C on the test board 120 from the FPGA 110 via the test channel 140, for example.

The loop channel 150 may extend from the FPGA 110 and may be connected to the FPGA 110 via the connector 130 and the test board 120. The loop channel 150 may not be electrically connected to the inner circuit of the test board 120. As a result, the loop channel 150 may not be electrically connected with the semiconductor chip C and may be used for checking the test board 120.

In exemplary embodiments in accordance with principles of inventive concepts, the loop channel 150 may include an input line 152, a loop line 154 and an output line 156. The input line 152 may extend from the FPGA 110 to the test board 120 via the connector 130. The output line 156 may extend from the test board 120 to the FPGA 110 via the connector 130. The loop line 154 may extend from the input line 152 in the test board 120. The loop line 154 may be connected to the output line 156. The test signal may be inputted from the FPGA 110 into the loop line 154 through the input line 152 and may be returned to the FPGA 110 through the output line 156. In exemplary embodiments in accordance with principles of inventive concepts, a signal outputted from the output line 156 may be measured and a correction value for correcting the test board 120 may be obtained based on the measured signal.

In exemplary embodiments in accordance with principles of inventive concepts, the input line 152 and the output line 156 may be positioned adjacent to each other. The loop channel 154 may have a relatively short trace that does not include the semiconductor chip C on the test board 120. That is, the loop line 154 may not surround the semiconductor chip C on the test board 120 and, in exemplary embodiments in accordance with principles of inventive concepts, because the loop line 154 may not pass through a central portion of the test board 120 where the semiconductor chip C may be positioned, the bending of the test board 120 may be indirectly checked, based on the test signal passing through the loop line. In this manner, in exemplary embodiments in accordance with principles of inventive concepts, the loop line 154 may be used for an electrical connection between the test board 120 and the connector 130.

In exemplary embodiments in accordance with principles of inventive concepts, the loop line 154 may correspond to spare channels of the test board 120. The spare channels may be formed in the test board during manufacturing and may be connected to each other to form the loop line 154. As a result, in exemplary embodiments in accordance with principles of inventive concepts, an additional process may not be required to form loop line 154, other than connecting the spare channels with each other.

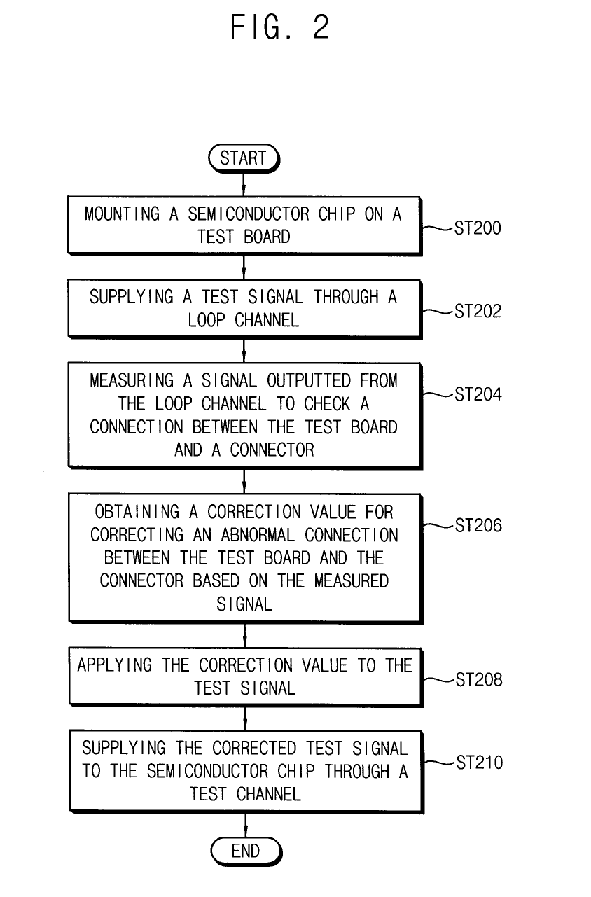

FIG. 2 is a flow chart illustrating an exemplary method of testing an electronic device using the apparatus in FIG. 1 in accordance with principles of inventive concepts.

Referring to FIGS. 1 and 2, in step ST200, the semiconductor chip C may be mounted on the central portion of the upper surface of the test board 120 and may be electrically connected to the inner circuit of the test board 120, which may be a multi-layer printed wiring, for example.

In step ST202, the test signal may be supplied from the FPGA 110 to the loop channel 150. The test signal may be returned to the FPGA 110 via the input line 152, the loop line 154 and the output line 156.

In step ST204, the signal outputted from the output line 156 may be measured to check an electrical connection between the test board 120 and the connector 130. In exemplary embodiments in accordance with principles of inventive concepts, when the electrical connection between the test board 120 and the connector 130 is abnormal, the measured signal outputted from the output line 156 may be different from the test signal inputted into the input line 152 and, a system and method in accordance with principles of inventive concepts may thereby detect and/or compensate for associated signal distortion.

In step ST206, a correction value, which may be employed, in accordance with principles of inventive concepts to compensate for the abnormal connection between the test board 120 and the connector 130, may be obtained based on the measured signal. In exemplary embodiments in accordance with principles of inventive concepts, characteristic values such as a delay, a resistance, etc., of the measured signal may be compared with characteristic values of the test signal to obtain the correction value.

In step ST208, the correction value may be applied to the test signal to obtain a corrected test signal. The corrected test signal may have characteristic values different from those of the test signal inputted into the input line 152. That is, the corrected test signal may be pre-compensated, based on the correction value, so that the test signal will have the initially desired characteristics of the test signal after passing through the connector and test board which cause the distortion, for example.

In step ST210, the FPGA 110 may supply the corrected test signal, also referred to herein as compensated, or pre-compensated, test signal, to the semiconductor chip C on the test board 120 through the test channel 140 to test electrical characteristics of the semiconductor chip C.

According to this exemplary embodiment in accordance with principles of inventive concepts, although the electrical connection between the test board 120 and the connector 130 may be abnormal, the semiconductor chip C may be tested using the corrected test signal taking the abnormal electrical connection into consideration so that test reliability of the semiconductor chip C may be improved. As a result, in accordance with principles of inventive concepts, when an abnormal electrical connection between the test board 120 and the connector 130 is generated, the semiconductor chip C may be tested using the test board 120 without using a separate check board and, consequently, the time required for testing the semiconductor chip C may be remarkably reduced.

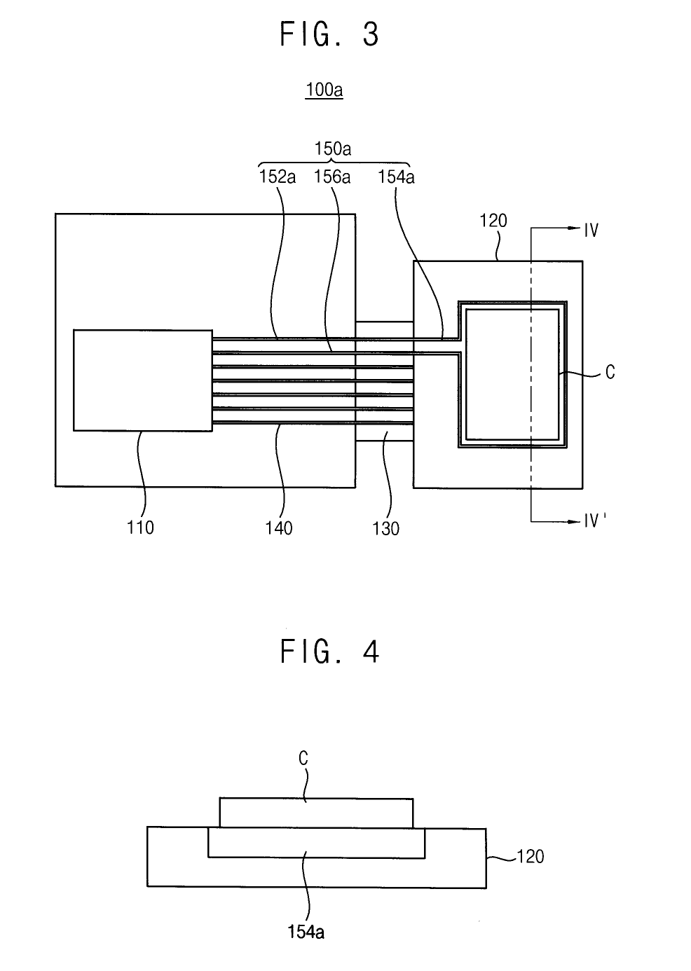

FIG. 3 is a plan view illustrating an apparatus for testing an electronic device in accordance with exemplary embodiments in accordance with principles of inventive concepts and FIG. 4 is a cross-sectional view taken along a line IV-IV′ in FIG. 3.

An apparatus 100a of this exemplary embodiment may include elements substantially the same as those of the apparatus 100 in FIG. 1 except for a loop channel. Thus, the same reference numerals may refer to the same elements and, for clarity and brevity of explanation, detained description of the same elements may not be repeated here.

Referring to FIGS. 3 and 4, a loop channel 150a in this exemplary embodiment in accordance with principles of inventive concepts may include an input line 152a, a loop line 154a and an output line 156a. The input line 152a and the output line 156a in FIG. 3 may be substantially the same as the input line 152 and the output line 156 in FIG. 1, respectively. Thus, for clarity and brevity of explanation detailed description of input line 152a and the output line 156a may not be repeated here.

In exemplary embodiments in accordance with principles of inventive concepts, the loop line 154a may be configured to surround the semiconductor chip C on the test board 120. Because the loop line 154a may pass through the central portion of the test board 120, where the semiconductor chip C may be positioned, any bending of the test board 120 may be directly checked, based on the test signal passing through the loop line 154a. Thus, the loop line 154a may be used for directly checking the bending of the test board 120.

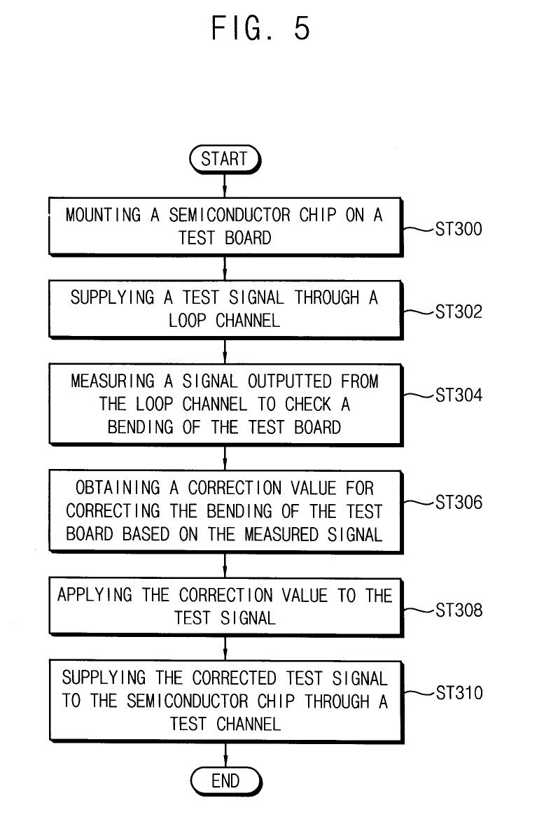

FIG. 5 is a flow chart illustrating an exemplary method of testing an electronic device using the apparatus in FIG. 3 in accordance with principles of inventive concepts.

Referring to FIGS. 3 and 5, in step ST300, the semiconductor chip C may be mounted on the central portion of the upper surface of the test board 120. The semiconductor chip C may be electrically connected to the inner circuit of the test board 120.

In step ST302, the test signal may be supplied from the FPGA 110 to the loop channel 150a. The test signal may be returned to the FPGA 110 via the input line 152a, the loop line 154a and the output line 156a. In exemplary embodiments in accordance with principles of inventive concepts, because the loop line 154a may surround the semiconductor chip C, the test signal may be returned to the FPGA 110 via the central portion of the test board 120.

In step ST304, the signal outputted from the output line 156a may be measured to directly check the bending of the test board 120 (through distortions in the test signal). In situations where the test board 120 is bent, the measured signal outputted from the output line 156a may be different from the test signal inputted into the input line 152a. That is, distortion may be generated in the test signal passing through the loop line 154a.

In step ST306, a correction value for correction the bending of the test board 120, that is, for example, a compensation value for compensating distortion of the test signal due to bending of the test board 120, may be obtained based on the measured signal. In exemplary embodiments in accordance with principles of inventive concepts, characteristic values such as a delay, a resistance, etc., of the measured signal may be compared with characteristic values of the test signal to obtain the correction value.

In step ST308, the correction value may be applied to the test signal to obtain a corrected test signal. As a result, the corrected test signal may have characteristic values different from those of the test signal inputted into the input line 152a. That is, the corrected signal may be pre-compensated for distortions due to bending of test board 120, so that the pre-compensated test signal delivered to the semiconductor chip C compensates for distortions due, for example, to bending of test board 120.

In step ST310, the FPGA 110 may supply the corrected test signal to the semiconductor chip C on the test board 120 through the test channel 140 to test electrical characteristics of the semiconductor chip C.

According to this exemplary embodiment, although the test board 120 may be bent and, as a result, may generate an abnormal electrical connection between the test board 120 and the connector 130, the semiconductor chip C may be tested using the corrected, or pre-compensated, test signal taking the abnormal electrical connection into consideration so that test reliability of the semiconductor chip C may be improved. Particularly, in situations where the test board 120 is bent, the semiconductor chip C may be tested using the bent test board 120 without using a separate check board so that a time for testing the semiconductor chip C may be remarkably reduced, as opposed to a method where a separate check board is used.

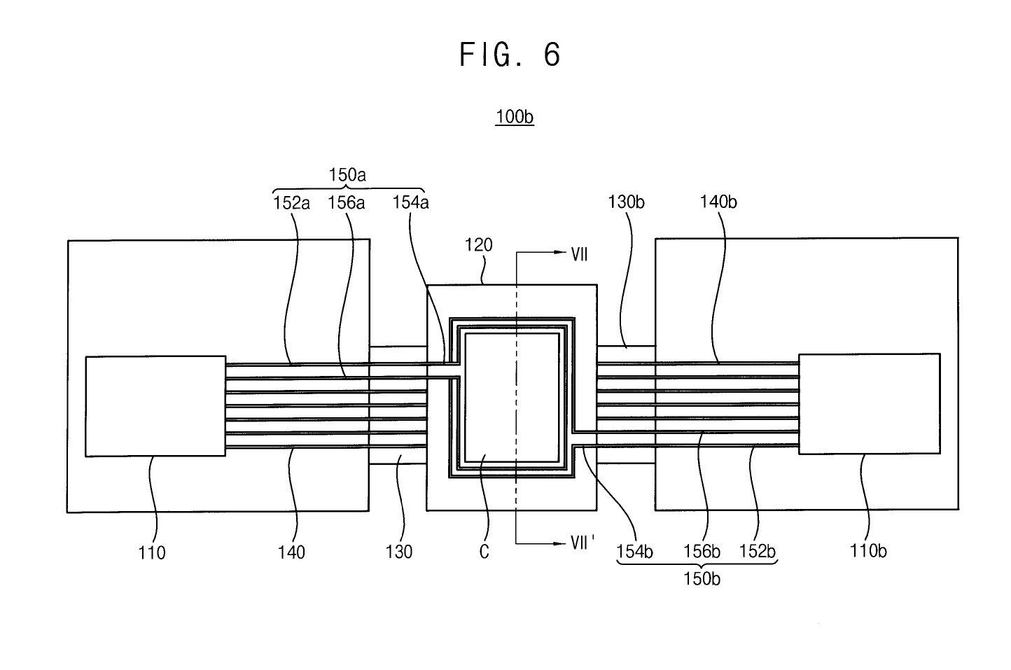

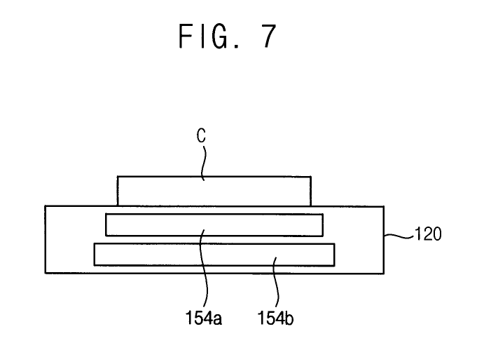

FIG. 6 is a plan view illustrating an apparatus for testing an electronic device in accordance with exemplary embodiments in accordance with principles of inventive concepts and FIG. 7 is a cross-sectional view taken along a line VII-VII′ in FIG. 6.

An apparatus 100b of this exemplary embodiment may include elements substantially the same as those of the apparatus 100a in FIG. 3, except for additionally including a second FPGA, a second connector, a second test channel and a second loop channel. Thus, the same reference numerals may refer to the same elements and, for clarity and brevity of description, detailed descriptions with respect to the same elements may not be repeated here.

Referring to FIGS. 6 and 7, a semiconductor chip C of this exemplary embodiment may include terminals that may not be tested using the single FPGA 110. As a result, an apparatus 100b of this exemplary embodiment may additionally include a second FPGA 110b, a second connector 130b, a second test channel 140b and a second loop channel 150b.

In exemplary embodiments in accordance with principles of inventive concepts, second FPGA 110b may be located opposite to the FPGA 110 with respect to the semiconductor chip C. The second connector 130b may be arranged between the semiconductor chip C and the second FPGA 110b. The second test channel 140b may be electrically connected between the second FPGA 110b and the inner circuit of the test board 120.

The second loop channel 150b may include a second input line 152b, a second loop line 154b and a second output line 156b. The input line 152a and the output line 156a of the loop channel 150a may be positioned at the connector 130 adjacent to a first end of a diagonal line on the semiconductor chip C. The input line 152b and the output line 156b of the second loop channel 150b may be positioned at a second end of the diagonal line on the semiconductor chip C opposite to the first end. That is, in exemplary embodiments in accordance with principles of inventive concepts, input and output lines of the first and second loop channels may be positioned substantially diagonally across the semiconductor chip C from one another. The second loop line 154b may extend from the second input line 152b, may surround the semiconductor chip C, and may be connected to the second output line 156b. In this manner, in accordance with principles of inventive concepts, the loop channel 150a and the second loop channel 150b may be symmetrical with each other with respect to the semiconductor chip C.

In exemplary embodiments in accordance with principles of inventive concepts, the loop line 154a may extend on a first plane and the second loop line 154b may extend in a second plane lower than the first plane. In accordance with principles of inventive concepts, when the test board 120 is not bent, the measured signal outputted from the loop line 154a may be substantially the same as the test signal outputted from the loop line 154b; but when the test board 120 is bent, the measured signal outputted from the loop line 154a may be different from the test signal outputted from the loop line 154b. In accordance with principles of inventive concepts, bending of the test board 120 which may result in a poor connection with the connector, which may result in a distorted test signal and which may be due, for example, to placement of semiconductor chip C on the test board 120, may be more accurately recognized using the loop line 154a and the second loop line 154b positioned on the different planes, for example.

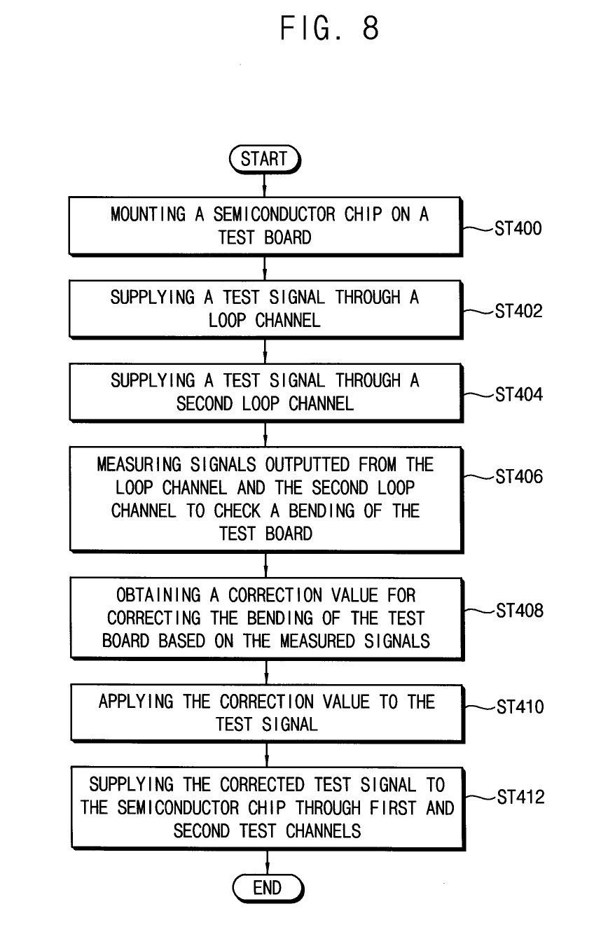

FIG. 8 is a flow chart illustrating an exemplary method of testing an electronic device using the apparatus in FIG. 6 in accordance with principles of inventive concepts.

Referring to FIGS. 6 and 8, in step ST400, the semiconductor chip C may be mounted on the central portion of the upper surface of the test board 120 for testing. The semiconductor chip C may be electrically connected to the inner circuit of the test board 120, which may include multi-layer wiring, for example.

In step ST402, the test signal may be supplied from the FPGA 110 to the loop channel 150a. The test signal may be returned to the FPGA 110 via the input line 152a, the loop line 154a and the output line 156a. In exemplary embodiments in accordance with principles of inventive concepts, because the loop line 154a may be configured to surround the semiconductor chip C, the test signal may be returned to the FPGA 110 via the central portion of the test board 120.

In step ST404, the test signal may be supplied from the second FPGA 110b to the second loop channel 150b. The test signal may be returned to the second FPGA 110b via the second input line 152b, the second loop line 154b and the second output line 156b. In exemplary embodiments in accordance with principles of inventive concepts, because the second loop line 154b may be configured to surround the semiconductor chip C, the test signal may be returned to the second FPGA 110b via the central portion of the test board 120.

In step ST406, the signals outputted from the output line 156a to the FPGA 110 and the second output line 156b to the second FPGA 110b may be measured and the measured signals may be compared with each other to directly check the bending of the test board 120. When the test board 120 is bent, the measured signal outputted from the output line 156a may be different from the measured signal outputted from the second output line 152b. That is, the distortion may be generated in the test signal passing through the loop line 154a and the second loop line 154b.

In step ST408, a correction value, or precompensation value, for correction, or pre-compensation of the test signal to accommodate the bending of the test board 120 may be obtained based on the measured signals. In exemplary embodiments in accordance with principles of inventive concepts, characteristic values such as a delay, a resistance, etc., of the measured signal may be compared with characteristic values of the test signal to obtain the correction value.

In step ST410, the correction value may be applied to the test signal to obtain a corrected, or pre-compensated, test signal. In accordance with principles of inventive concepts, the corrected test signal may have characteristic values different from those of the test signal inputted into the input line 152a and the second input line 152b.

In step ST412, the FPGA 110 and the second FPGA 110b may supply the corrected test signal to the semiconductor chip C on the test board 120 through the test channel 140 and the second test channel 140b to test electrical characteristics of the semiconductor chip C.

According to this exemplary embodiment, the bending of the test board may be more accurately recognized using the loop lines positioned on different planes and test reliability of the semiconductor chip C may thereby be improved.

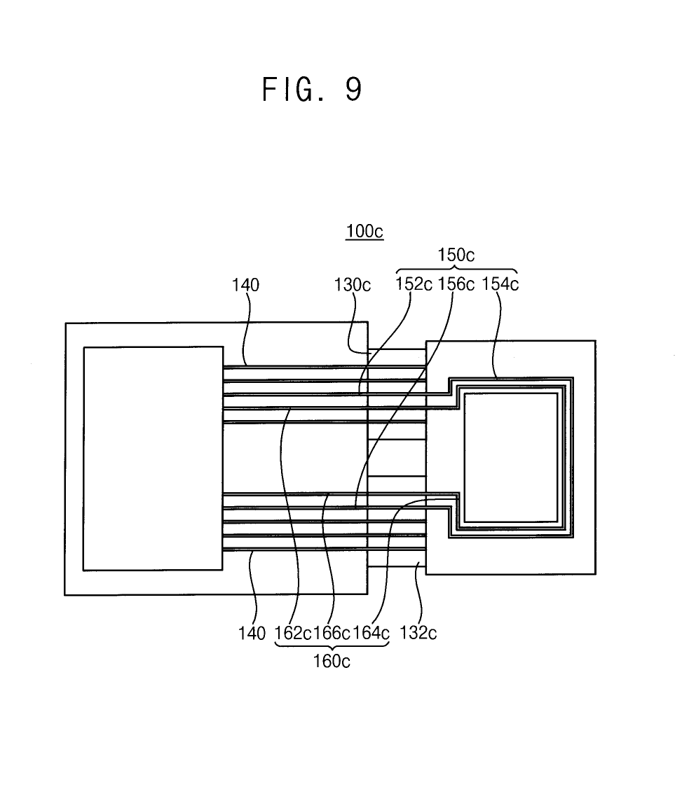

FIG. 9 is a plan view illustrating an apparatus for testing an object such as an electronic device in accordance with exemplary embodiments in accordance with principles of inventive concepts.

An apparatus 100c of this exemplary embodiment may include elements substantially the same as those of the apparatus 100b in FIG. 6 except for an FPGA. Thus, for clarity and brevity of explanation the same reference numerals may refer to the same elements and descriptions with respect to the same elements may not be repeated here.

Referring to FIG. 9, an apparatus 100c of this exemplary embodiment may include a single FPGA 110, a test board 120, a first connector 130c, a second connector 132c, a test channel 140, a first loop channel 150c and a second loop channel 160c.

In exemplary embodiments in accordance with principles of inventive concepts, the FPGA 110 may be single. That is, FPGA may be a single chip and the first connector 130c and the second connector 132c may be arranged between the single FPGA 110 and the test board 120.

The first loop channel 150c may include a first input line 152c, a first loop line 154c and a first output line 156c. The first input line 152c may pass through the first connector 130c. The first output line 156c may pass through the second connector 132c. The first loop line 154c may extend from the first input line 152c on the first plane, may be configured to surround the semiconductor chip C and may be connected to the first output line 156c.

The second loop channel 160c may include a second input line 162c, a second loop line 164c and a second output line 166c. The second input line 162c may pass through the first connector 130c. The second output line 166c may pass through the second connector 132c. The second loop line 164c may extend from the second input line 162c on the second plane, may be configured to surround the semiconductor chip C, and may be connected to the second output line 166c. In exemplary embodiments in accordance with principles of inventive concepts, the first loop line 154c and the second loop line 164c may not surround a side surface of the semiconductor chip C oriented toward the FPGA 110.

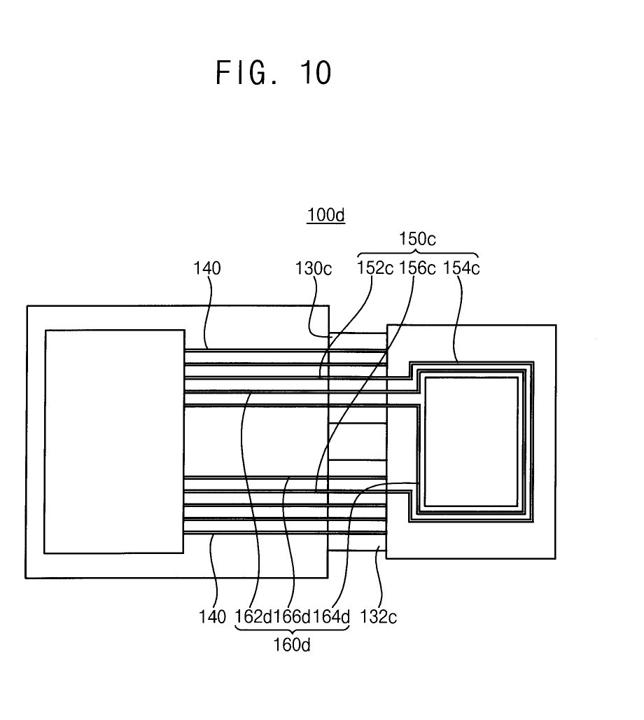

FIG. 10 is a plan view illustrating an apparatus for testing an electronic device in accordance with exemplary embodiments in accordance with principles of inventive concepts.

An apparatus 100d of this exemplary embodiment in accordance with principles of inventive concepts may include elements substantially the same as those of the apparatus 100c in FIG. 9 except for a second loop channel. As a result, the same reference numerals may refer to the same elements and, for clarity and brevity of explanation, detailed description with respect to the same elements will not be repeated here.

Referring to FIG. 10, a second loop channel 160d of this exemplary embodiment may include a second input line 162d, a second loop line 164d and a second output line 166d. The second input line 162d may pass through the first connector 130c. The second output line 166d may also pass through the first connector 130c. The second loop line 164d may extend from the second input line 162d on the second plane, may be configured to surround the semiconductor chip C, and may be connected to the second output line 166d. In exemplary embodiments in accordance with principles of inventive concepts, because the second output line 166d may pass through the first connector 130c, the second loop line 164d may be configured to surround the side surface of the semiconductor chip C oriented toward the FPGA 110.

In exemplary embodiments in accordance with principles of inventive concepts, the object under test may include a semiconductor chip, or may include other electronic devices.

According to exemplary embodiments in accordance with principles of inventive concepts, a spare channel in the test board may be used as the loop channel. As a result, a test board may be rapidly checked based on the test signal outputted from the loop channel and the test board may be checked without an additional check board. Additionally, because a correction value, or, precompensation value, may be applied to the test signal, the electronic device on the test board may be tested using the corrected, or precompensated, test signal without suspending testing and, as a result time required for testing the electronic device may be remarkably reduced.

The foregoing is illustrative of exemplary embodiments in accordance with principles of inventive concepts and is not to be construed as limiting thereof. Although exemplary embodiments in accordance with principles of inventive concepts have been described, those skilled in the art will readily appreciate that many modifications are possible in the exemplary embodiments in accordance with principles of inventive concepts without materially departing from the novel teachings and advantages of inventive concepts. Accordingly, all such modifications are intended to be included within the scope of inventive concepts as defined in the claims. In the claims, means-plus-function clauses are intended to cover the structures described herein as performing the recited function and not only structural equivalents but also equivalent structures.

What is claimed is:

1. An apparatus for testing an electronic device, the apparatus comprising:
a field programmable gate array (FPGA) configured to test the electronic device;
a test board electrically connected to the electronic device;
a test channel electrically connected between the electronic device and the FPGA via the test board; and
a loop channel extending from the FPGA to the test board, and returning to the FPGA, the loop channel configured to test the test board.

2. The apparatus of claim 1, wherein the loop channel comprises:
an input line extending from the FPGA;
a loop line extending from the input line in the test board; and
an output line extending from the loop line and connected to the FPGA.

3. The apparatus of claim 2, wherein the loop line is configured to surround the electronic device on the test board.

4. The apparatus of claim 2, wherein the loop line comprises:
a first loop line extending on a first plane and configured to surround the electronic device on the test board; and
a second loop line extending on a second plane and configured to surround the electronic device on the test board.

5. The apparatus of claim 1, further comprising a connector arranged between the FPGA and the test board, the test board detachably connected to the connector.

6. The apparatus of claim 5, wherein the connector comprises a first connector and a second connector respectively arranged at opposite sides of the electronic device on the test board.

7. The apparatus of claim 6, wherein the loop channel comprises:
a first loop channel extending from the FPGA via the first connector in the test board on a first plane; and
a second loop channel extending from the FPGA via the second connector in the test board on a second plane.

8. The apparatus of claim 7, wherein the first loop channel and the second loop channel are configured to surround the electronic device on the test board.

9. The apparatus of claim 7, wherein the first loop channel and the second loop channel are symmetrical with each other with respect to the electronic device on the test board.

10. The apparatus of claim 9, wherein the first loop channel extends from a portion of the first connector adjacent to a first end of a diagonal line on the electronic device, and the second loop channel extends from a portion of the second connector adjacent to a second end of the diagonal line opposite to the first end.

11. The apparatus of claim 1, wherein the electronic device comprises a semiconductor chip.

12. A method of testing an electronic device, the method comprising:
inputting a test signal to a test board via a loop channel, the loop channel extending from a field programmable gate array (FPGA) configured to test the electronic device, and connected to the FPGA via the test board;
measuring a signal outputted from the test board to the FPGA via the loop channel;
checking the test board based on the measured signal to obtain a correction value for compensating for distortions related to the test board;
applying the correction value to the test signal to obtain a corrected test signal; and
supplying the corrected test signal to the electronic device through a test channel electrically connected between the electronic device and the FPGA via the test board.

13. The method of claim 12, wherein inputting the test signal to the test board comprises supplying the test signal through the loop line configured to surround the electronic device on the test board.

14. The method of claim 12, wherein inputting the test signal to the test board comprises:
supplying the test signal through a first loop line on a first plane; and
supplying the test signal through a second loop line on a second plane.

15. The method of claim 12, wherein inputting the test signal to the test board comprises supplying the test signal through a connector.

16. A method, comprising:
sending a test signal from a tester through a loop channel on a board upon which a semiconductor chip to be tested is mounted;
receiving the test signal after passage through the channel;
comparing the sent test signal with the received test signal to detect distortion of the test signal;
developing a compensation signal;
combining the compensation signal and test signal to form a compensated test signal; and
testing the semiconductor chip using the compensated test signal transmitted through a test channel.

17. The method of claim 16, wherein the test signal and compensated test signal are generated by an FPGA.

18. The method of claim 16, wherein the loop channel does not surround the semiconductor chip.

19. The method of claim 16, wherein the loop channel surrounds the semiconductor chip and is distributed on two levels of the board.

20. The method of claim 19, wherein the loop channel includes two components, each receiving test signals from separate FPGAs.
